(19) United States
(12) Patent Application Publication
(10) Pub. No.: US 2002/0097039 A1
(43) Pub. Date: Jul. 25, 2002

(54) Strain gauge and method

(76) Inventors: Butrus T. Khuri-Yakub, Palo Alto, CA (US); Abdullah Atalar, Ankara (TR); Arif S. Ergun, Mountain View, CA (US)

Correspondence Address: Aldo J. Test, FLEHR HOHBACH TEST ALBRITTON & HERBERT LLP, Suite 3400, Four Embarcadero Center, San Francisco, CA, 94111-4187, US

(21) Appl. No.: 09/736,921

(22) Filed: Dec. 13, 2000

Related U.S. Application Data
(60) Provisional application No. 60/172,330, filed on Dec. 17, 1999.

(51) Int. Cl. G01R 23/04

(52) U.S. Cl. 324/95

(57) ABSTRACT

An r.f. probed strain gauge is described. The strain gauge is in the form of an r.f. transmission line where electrical characteristics (r.f. impedance and propagation contrast) vary with strain in the element or structure whose strain is being measured.

### RELATED APPLICATIONS

This application claims priority to provisional application serial No. 60/172,330 filed Dec. 17, 1999.

### BRIEF DESCRIPTION OF THE INVENTION

This invention relates generally to strain gauges and method of operation, and more particularly to an r.f. probed strain gauge and method of operation.

### BACKGROUND OF THE INVENTION

It is well known that high frequency electronic circuits are different from low frequency circuits in the sense that the wavelength of the signal used is comparable with the circuit's physical dimensions. As a result, signals are strongly affected by the geometry and the electrical properties of the medium in which they travel. A slight change in geometry or electrical properties may result in substantial changes in the amplitude and/or the phase of the high frequency signal. This fact makes high frequency electronic circuits design more critical than low frequency electronic circuits design. On the other hand, this sensitivity of the high frequency signals to the geometry and the electrical properties of the medium can be utilized to make very sensitive detectors which depend on variations in such properties of the medium.

A lumped element equivalent circuit model of a high frequency transmission line is shown in FIG. 1. The characteristic impedance and the propagation constant of the transmission line are determined by the values of the inductance L and the capacitance C. On the other hand, L and C are determined by the geometry and the electrical properties of the medium in which they are found.

### OBJECTS AND SUMMARY OF THE INVENTION

It is an object of this invention to make use of the characteristics of a high frequency transmission line to provide a sensitive strain gauge.

The foregoing objective is accomplished by providing a strain gauge in which the strain is measured by measuring the change in the electrical impedance and propagation constant of a high frequency transmission line responsive to strain.

### BRIEF DESCRIPTION OF THE DRAWINGS

The invention will be more clearly understood from the following description when read in conjunction with the accompanying drawings in which:

FIG. 1 is a lumped element equivalent circuit of a high frequency transmission line.

FIG. 2 is a perspective view of a strain gauge in accordance with an embodiment of the present invention.

FIG. 3 schematically illustrates an interferometric strain detection system.

FIG. 4 is a top plan view schematically illustrating a strain gauge with integrated electronics.

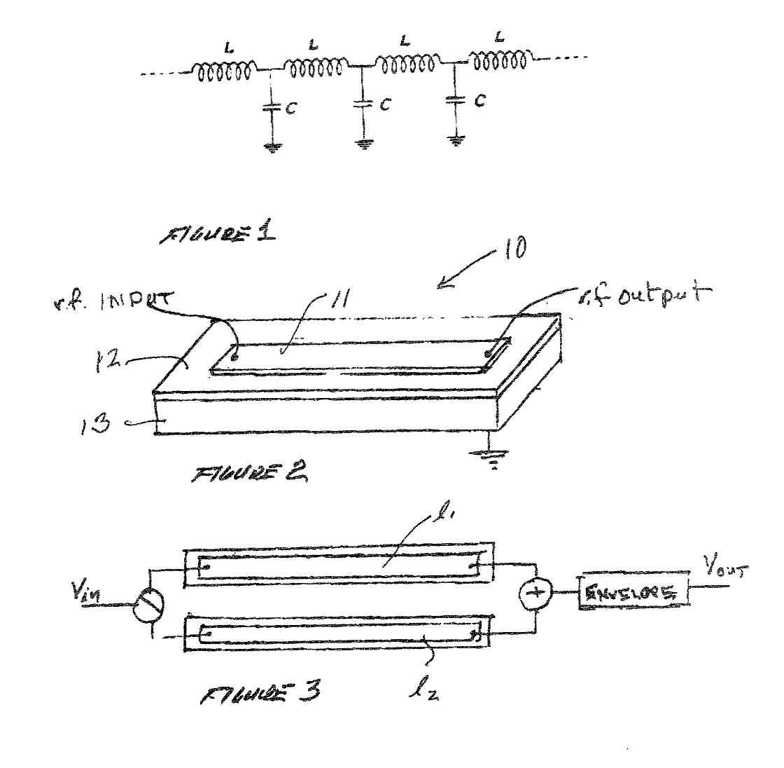

### DETAILED DESCRIPTION OF THE INVENTION

FIG. 2 shows a strain gauge fabricated in accordance with one embodiment of the invention. The strain gauge comprises a microstrip transmission line 10. The transmission line includes a conductive strip 11 deposited on an insulating member 12 which is supported on a conductive substrate 13. For example, the microstrip transmission line can be fabricated by growing an insulating layer such as silicon oxide on a silicon substrate. A thin film conductive strip is then formed by depositing a thin metal layer on the surface of the oxide through a suitable photomask. In the alternative, a metal layer is formed on the surface of the oxide and by masking and etching metal is removed leaving the conductive strip. Techniques for forming metal strips are well known in the electronic art. The microstrip transmission line can also be formed on an insulating layer such as a ceramic layer carried by a conductive metal substrate. In certain applications, where the element or structures where strain is to be monitored is conductive, the strain gauge can comprise an insulating layer adhered to the element with a conductive strip formed on the insulating layer. The present invention does not rely on the manner of forming the microstrip transmission line but rather on the employment of the characteristics of a microstrip transmission line which provide a sensing element whose r.f. impedance and propagation constant vary with strain in the element or structure.

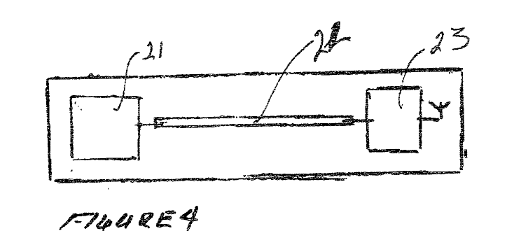

An example of an r.f. probed strain gauge employs two microstrips, 1₁ and 1₂, connected in an interferometric circuit, FIG. 3. The input r.f. signal Vᵢₙ is divided by divider 16 and applied to the lines 1₁ and 1₂. The output r.f. is combined in combiner 17 and applied to envelope detector 18. The output voltage Vₒᵤₜ represents the strain. The lines l₁ and l₂ have equal characteristic impedance (Z₀) and the propagation constant (β). If the lengths of the lines are also equal, then the output (Vₒᵤₜ) is equal to the amplitude of the input signal (V_{RF}) assuming that the divider 16 and combiner 17 are ideal. However, if the line lengths are not equal, then the output is determined by the electrical length difference between the two transmission lines.

Suppose that one of the transmission lines is used as a reference with a length l=l₀+l_{d}, which is fixed. Suppose also that the other line has a length of l₁=l₀, which is not fixed but rather changes by external stress or strain. Then, the output voltage is,

$$\frac{{V}_{RF}}{2} \sqrt{2 ( {l}_{1}} + cos β ld - β Δ l ) \qquad ( 1 )$$

where Δl is the physical change in the length of the line. By choosing βl_{d}=(2k+1)π, and assuming that the strain on the line is very small (βΔl<<1), then the output voltage can be written as

$${V}_{out} = \frac{{V}_{RF}}{\sqrt{2}} ( 1 + \frac{βΔ l}{2} ) \qquad ( 2 )$$

Thus, the change in the output voltage as a function of Δl can be written as in Equation 3, where Φ₀=βl₀ is the electrical length of the line.

$$Δ {V}_{out} = \frac{{V}_{RF}}{2 \sqrt{2}} {Φ}_{0} \frac{Δ l}{{l}_{0}} \qquad ( 3 )$$

The factor Δl/l₀ in equation 3 is actually the strain along the length of the transmission line. By using a very high frequency RF signal it is possible to measure the strain on the transmission line in a very sensitive manner. Besides, due to the nature of the interferometer any phase noise generated by the RF source is canceled, resulting in very low noise measurements. Thus, this method can be used in strain measurements to make very sensitive strain gauges.

As an example consider transmission lines that are deposited on a silicon substrate in the form of microstrip lines with their characteristic impedance adjusted to be 50 Ω, and l₀ chosen to be 1 mm. The reference line l₁ has a fixed length, whereas the other line, l₂, is subject to a strain. Roughly, the wave velocity in these transmission lines is 1×10⁸ m/s. Then, for a RF signal of 1 GHz frequency, and 3 V amplitude, the change in the output voltage is,

$$Δ {V}_{out} ≅ 0.064 \frac{Δ l}{{l}_{0}} \qquad ( V )$$

By assuming only thermal noise (which is quite true, since using RF detection eliminates 1/f noise, and making an interferometric detection eliminates any phase noise due to the oscillator) the minimum strain that can be measured turns out to be 1.4×10⁻⁸/✓Hz, which is quite good. Note that the line length is only 1 mm. A longer line would provide proportionately increased output voltage. Another method of increasing the sensitivity is to increase the r.f. frequency.

Another way to measure the change in electrical characteristics of the microstrip transmission line responsive to the strain is to incorporate one line in the feedback path of an r.f. oscillator. The output frequency of the oscillator will then depend upon the electrical characteristics of the microstrip transmission line. A further way would be to use the input r.f. as a reference and then measure the change in phase of the output with respect to the input r.f. signal.

The strain gauge can be build ton a silicon or GaAs substrate. This would permit building electronic circuits on the substrate which could provide the r.f. input and transmit the r.f. output to a remote location for processing, thus providing a wireless strain gauge. A chip integrated with r.f. input circuit 21, transmission line 22, and r.f. output circuit 23 is schematically shown in FIG. 4. The input and output r.f. circuits are conventional integrated circuits.

Thus, there has been provided a sensitive strain gauge. The strain gauge employs a microstrip transmission line as the sensing element with the transmission line connected in an r.f. detecting circuit. The sensitivity is dependent upon the configuration (length) of the transmission line and the r.f. frequency.

What is claimed is:

1. A strain gauge for measuring strain in an element comprising
a microstrip transmission line coupled to the element,
means for applying an input r.f. voltage to one end of the microstrip transmission line, and
means for receiving the r.f. output voltage from the other end of the line and generating an output signal related to the change in electrical characteristics of the microstrip transmission line resulting from the strain in the element to which it is coupled.

2. A strain gauge as in claim 1 including an r.f. input current for applying the input r.f. voltage to said one end and an r.f. output current for transmitting the output signal.

3. A strain gauge comprising an r.f. transmission line including a conductive strip supported on an insulating member above a ground plane.

4. A strain gauge for measuring strain in an element comprising
a reference microstrip transmission line,
a strain measuring microstrip transmission line for coupling to the element,
means for applying an input r.f. voltage to the ends of said microstrip transmission lines,
means for receiving and combining the output voltage received from the other end of the lines, and
means for receiving and processing the combined output voltage to provide an output signal indicative of the change in electrical characteristics of the strain measuring microstrip transmission line resulting from strain in said element.

5. A strain gauge as in claim 4 including an r.f. input current for applying the input r.f. voltage to said one end and an r.f. output current for transmitting the output signal.

6. A strain gauge for measuring strain in an element comprising
an r.f. oscillator circuit, and
a microstrip transmission line coupled to the element and connected in said r.f. oscillator circuit to control the frequency of said oscillator circuit responsive to changes in electrical characteristics of said microstrip transmission line resulting from strain in said element.
